(19) United States
(12) Patent Application Publication
(10) Pub. No.: US 2013/0141910 A1
(43) Pub. Date: Jun. 6, 2013

(54) Method for assembling LEDs to a ceramic heat conductive piece and a structure produced by the method

(71) Applicant: Tzu-Yu Liao, Taichung City (TW)

(72) Inventor: Tzu-Yu Liao, Taichung City (TW)

(21) Appl. No.: 13/310,765

(22) Filed: Dec. 4, 2011

(51) Int. Cl. F21V 29/00; C04B 41/51; H01L 21/64; F21V 21/00; H01R 43/02

(52) U.S. Cl. 362/249.02; 29/854

(57) ABSTRACT

A method for assembling LEDs to a ceramic heat conductive piece comprises: mixing ceramic materials together and subjecting the mixed ceramic materials to hot pressing to form the ceramic heat conductive piece, the ceramic heat conductive piece has a cold end; subjecting the cold end of the ceramic heat conductive piece to sliver printing, drying process and silver reduction process to form the silver layer; choosing conductive binders, and applying the conductive binders to the silver layer by coating process; attaching the LEDs between paired conductive binders by welding; getting a finished product. The structure produced by the method is such that the LEDs are located between the paired conductive binders, and each of the LEDs includes a LED wafer disposed on a substrate, so that the heat generated by the LEDs can be transmitted quickly to the ceramic heat conductive piece via the conductive binders and the silver layer.

### BACKGROUND OF THE INVENTION

1. Field of the Invention

The present invention relates to a method for assembling LEDs to a ceramic heat conductive piece and a structure produced by the method, which is capable improving heat dissipation while reducing light decline.

2. Description of the Prior Art

LED (Light Emitting Diode) has been widely used. However, LED related products are not often seen in the market because the temperature of a lighting LED is very high, and if heat dissipation is not good, the light of the LED will decline, or even the LED will be damaged.

Hence, many LED related products are designed to have an exposed heat dissipation structure. For example, the lamp holder is designed as a heat dissipation structure which is non-metal and formed with a plurality of thermal holes. The exposed heat dissipation structure not only looks ugly, but also is likely to burn the user. Therefore, some heat dissipation structures of the LED are designed to be located inside the lamp holder, wherein the lampshade is made of porous material, LED is disposed in the lampshade, and outside the lampshade is covered a metal cover. There is a large distance between the LED and the inner surface of the lampshade. The heat produced by the LED is transmitted to the lampshade by thermal radiation and finally radiated into ambient air via the metal cover. However, the thermal radiation has a very low heat dissipation efficiency and is unable to take away the heat generated by the LED in a short period of time, consequently causing heat accumulation and light decline. Another type of heat dissipation device is provide with heat dissipation plates which are connected one another, and only the middle portions of the respective heat dissipation plates are in contact with one another, so that the heat dissipation passage is too narrow, and as a result, the heat dissipation efficiency is low.

There is a patent in Taiwan, which is another invention of the author of the present invention, disclosed another heat dissipation structure, wherein the LED lamp is disposed on a ceramic base which is used as a heat dissipation structure.

The present invention has arisen to mitigate and/or obviate the afore-described disadvantages.

### SUMMARY OF THE INVENTION

The primary object of the present invention is to provide a method for assembling LEDs to a ceramic heat conductive piece and a structure produced by the method, which is capable improving heat dissipation while reducing light decline.

To achieve the above object, a method for assembling LEDs to a ceramic heat conductive piece in accordance with the present invention comprises: the following steps:
step of forming the ceramic heat conductive piece: mixing different ceramic materials together and subjecting the mixed ceramic materials to hot pressing to form the ceramic heat conductive piece, the ceramic heat conductive piece has a cold end:
step of forming a silver layer: subjecting a surface of the cold end of the ceramic heat conductive piece to sliver printing, drying process and silver reduction process to form the silver layer;
step of wiring: choosing conductive binders, and applying the conductive binders to the silver layer by coating process;
step of attaching and welding: attaching the LEDs between paired conductive binders by welding, so that the LEDs and the conductive binders form an electric circuit loop;
step of getting a finished product: after the LEDs are welded, the ceramic heat conductive piece is connected to power wires and a ground wire, so that a final product of ceramic heat conductive piece 30 is obtained.

A structure produced by the method comprises the silver layer formed along a predetermined route on the surface of the cold end of the ceramic heat conductive piece, the LEDs are located between the paired conductive binders, and each of the LEDs includes a LED wafer disposed on a substrate, so that the heat generated by the LEDs can be transmitted quickly to the ceramic heat conductive piece via the conductive binders and the silver layer.

The present invention will become more obvious from the following description when taken in connection with the accompanying drawings, which show, for purpose of illustrations only, the preferred embodiments in accordance with the present invention.

### BRIEF DESCRIPTION OF THE DRAWINGS

FIG. 1 is a perspective view of a lamp with a ceramic heat conductive piece in accordance with the present invention;

FIG. 2 is an exploded view of the lamp with a ceramic heat conductive piece in accordance with the present invention;

FIG. 3 is an assembly view of the lamp in accordance with the present invention;

FIG. 4 is an illustrative view of the ceramic heat conductive piece in accordance with the present invention;

FIG. 5 is a flow chart showing the steps of method for assembling LEDs to the ceramic heat conductive piece in accordance with the present invention;

FIG. 6 is an illustrative view showing the method for assembling LEDs to the ceramic heat conductive piece in accordance with the present invention; and

FIG. 7 is an illustrative view showing how the LEDs are connected.

### DETAILED DESCRIPTION OF THE PREFERRED EMBODIMENTS

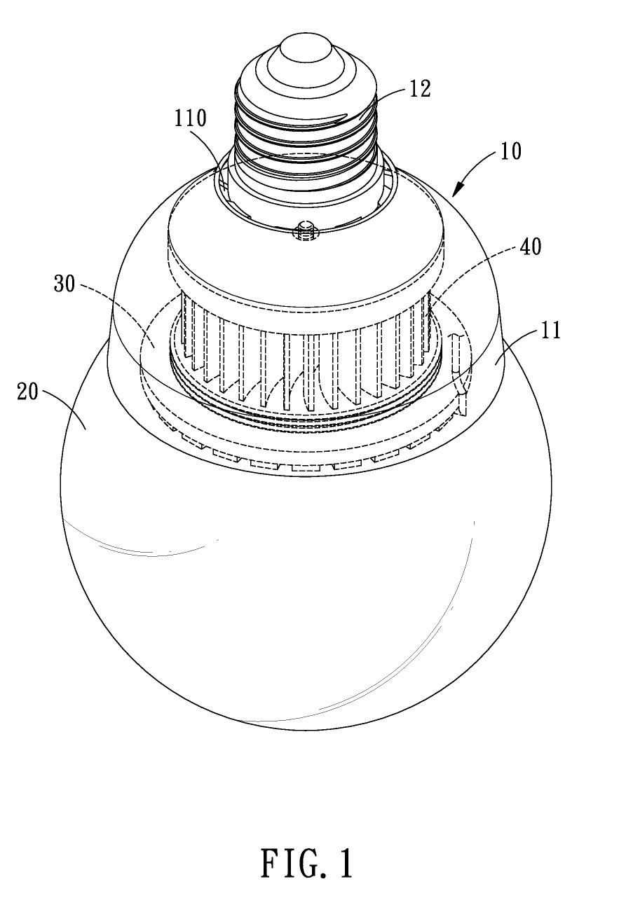

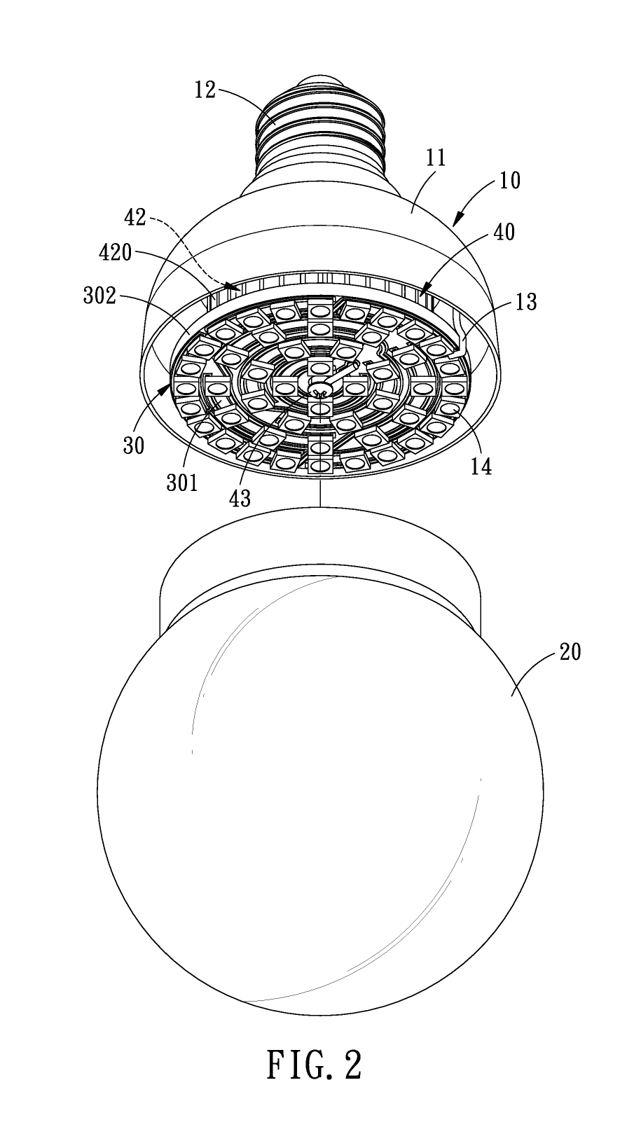

Referring to FIGS. 1-3, a lamp of the present invention comprises a lamp holder 10 and a lamp shell 20 mounted on the lamp holder 10. The lamp holder 10 comprises a housing 11 which has one end for mounting the lamp shell 20 and has another end formed with an electric connecting portion 12 for electrically connecting to power source. The electric connecting portion 12 is electrically connected to a plurality of LEDs (Light Emitting Diodes) 14 disposed inside the housing 11 by electric wires 13. The bottoms of all the LEDs 14 are fixed to one side of a unitary ceramic heat conductive piece 30, and another side of the ceramic heat conductive piece 30 is connected to one end of a heat dissipation member 40. Another end of the heat dissipation member 40 is fixed to the bottom of the housing 11. The ceramic heat conductive piece 30 has a cold end 301 facing the LEDs 14 and a heat end 302 facing the heat dissipation member 40.

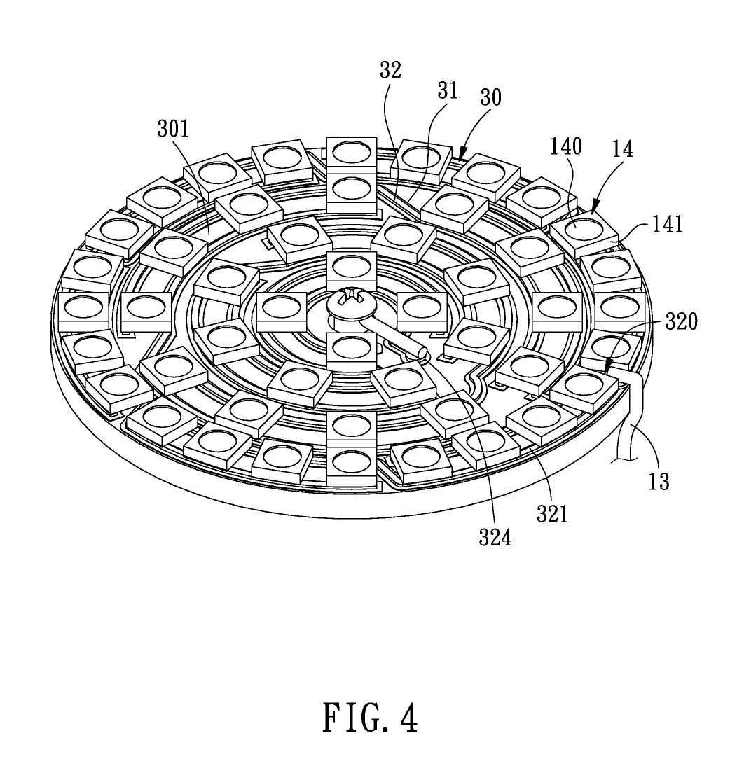

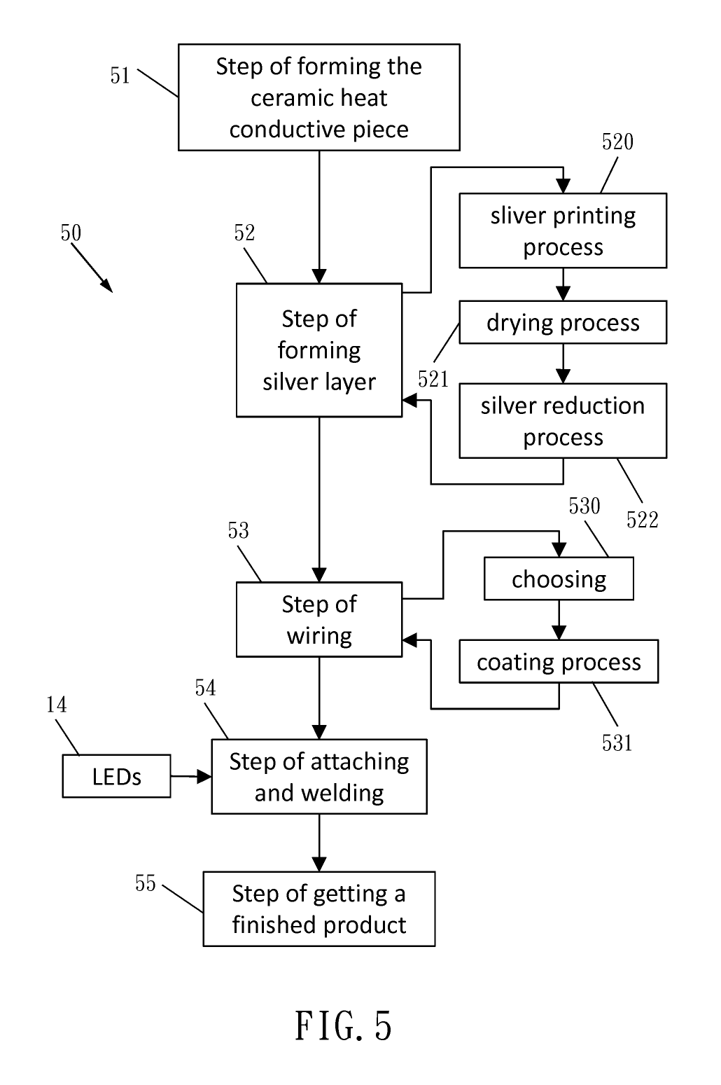

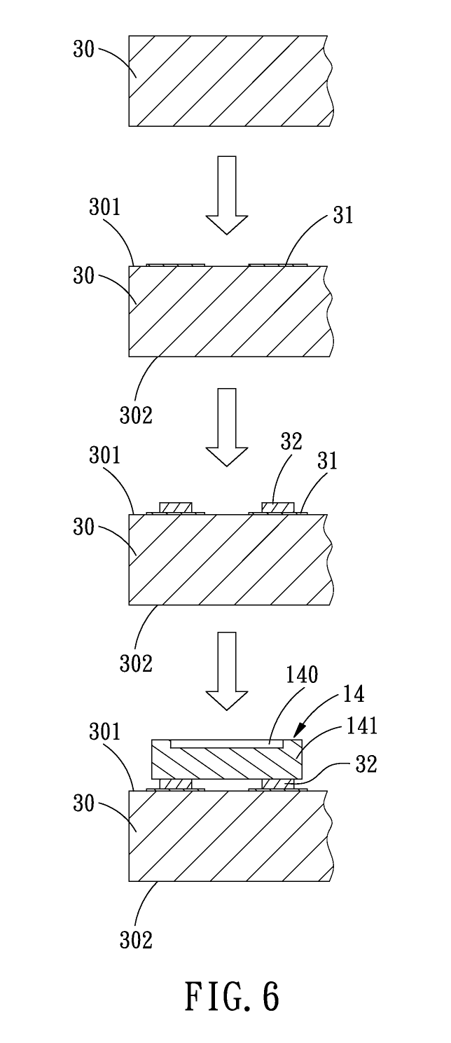

The method 50 for assembling the LEDs 14 to the ceramic heat conductive piece 30 comprises the following steps, with reference to FIGS. 4-7.

Step 51 of forming the ceramic heat conductive piece: Magnesium oxide, aluminum oxide or aluminum nitride, silicon dioxide, zinc oxide, niobium oxide or bismuth oxide or zirconium oxide, these ceramic materials, are mixed in certain proportion and then subjected to hot pressing a temperature of 350-1400° C. and pressure of 150-250 tons for 1-15 seconds to form the ceramic heat conductive piece 30, and the proportions are such that 10-15% Magnesium oxide, 65-70% aluminum oxide or aluminum nitride, 10-15% silicon dioxide, 5-10% zinc oxide, 5-10% niobium oxide or bismuth oxide or zirconium oxide.

Step 52 of forming silver layer: the surface of the cold end 301 of the ceramic heat conductive piece 30 is subjected to sliver printing process 520, drying process 521 and silver reduction process 522 to form a silver layer 31 of certain thickness along a predetermined route. The sliver printing 520 is performed along the predetermined route on the surface of the cold end 301 to form the silver layer 31 with a thickness of 0.1-0.5 mm, or can be performed by manual coating. The sliver layer 31 is composed of 40-60% sliver powder, and 40-60% silica binder. After the silver printing process 520, the drying process 521 is performed at a temperature of 120-200 ° C. for 8-22 minutes, and meanwhile the silver reduction process 522 is performed at a temperature of 700-800 ° C. for 1-3 hours to deoxidize the silver layer 31.

Step 53 of wiring: choosing (530) conductive binders 32, and the conductive binders 32 in accordance with the present invention is Tin paste composed of 50-60% Tin and 40-50% additive. Then the conductive binders 32 are applied to the silver layer 31 by coating process 531.

Step 54 of attaching and welding: attaching the LEDs 14 between the paired conductive binders 32 by welding, so that the LEDs 14 and the conductive binders 32 form an electric circuit loop with a voltage below 36 volts and a current of 250 mA.

Step 55 of getting a finished product: after the LEDs 14 are welded, the ceramic heat conductive piece 30 can be connected to drive circuit after being provided with power wires and a ground wire, so that a final product of ceramic heat conductive piece 30 is finished.

The final product made by the aforementioned method is shown in FIG. 4, on the surface of the cold end 301 of the ceramic heat conductive piece 30 is formed the silver layer 31 which is arranged along a predetermined route. On the silver layer 31 are further provided the conducive binders 32, and the LEDs 14 are located between the paired conductive binders 32. Each of the LEDs 14 includes a LED wafer 140 disposed on a substrate 141, so that the heat generated by the LEDs 14 can be transmitted quickly to the ceramic heat conductive piece 30 via the conductive binders 32 and the silver layer 31.

The conductive binder 32 and the silver layer 31 are made of highly electric and thermal conductive material. Furthermore, the sliver layer 31 can be easily filtered into the clearance of the ceramic heat conductive piece 30 since it is composed of small and fine particles, enabling the silver layer 31 and the ceramic heat conductive piece 30 to be better jointed, the heat can be effectively transmitted to the ceramic heat conducive piece 30, and the voltage of the conductive binders 32 and the silver layer 31 can make the ceramic heat conducive piece 30 get more thermal electromotive force.

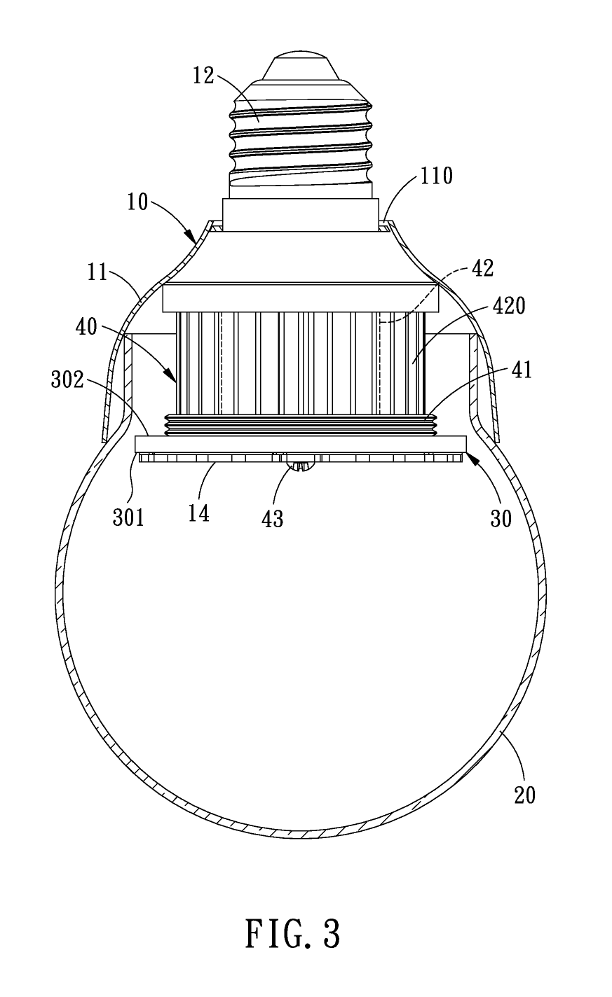

The heat dissipation member 40, as shown in FIG. 3, includes a heat conductive panel 41 which is the same size as the ceramic heat conducive piece 30 and has a side contacting the ceramic heat conducive piece 30, so that the heat can be transmitted from the hot end 302 of the ceramic heat conductive piece 30 to the heat conductive panel 41. Another side of the heat conductive panel 41 is provided at a center thereof with a central rod 42, and a fixing pin 43 is inserted through the center of the central rod 42 and into the bottom of the housing 11. A plurality of wings 420 is arranged around the central rod 42 in a radial manner and extends from the heat conductive panel 41. Each of the wings 420 has one end connected to the central rod 42 and another end connected to the heat conductive panel 41, so that heat can be quickly and efficiently transmitted to the wings 420 and dissipated from the surface of the wings 420.

To improve heat dissipation, at the bottom of the housing 11 is further provided a plurality of holes 110 for dissipating the heat from the heat dissipation member 40.

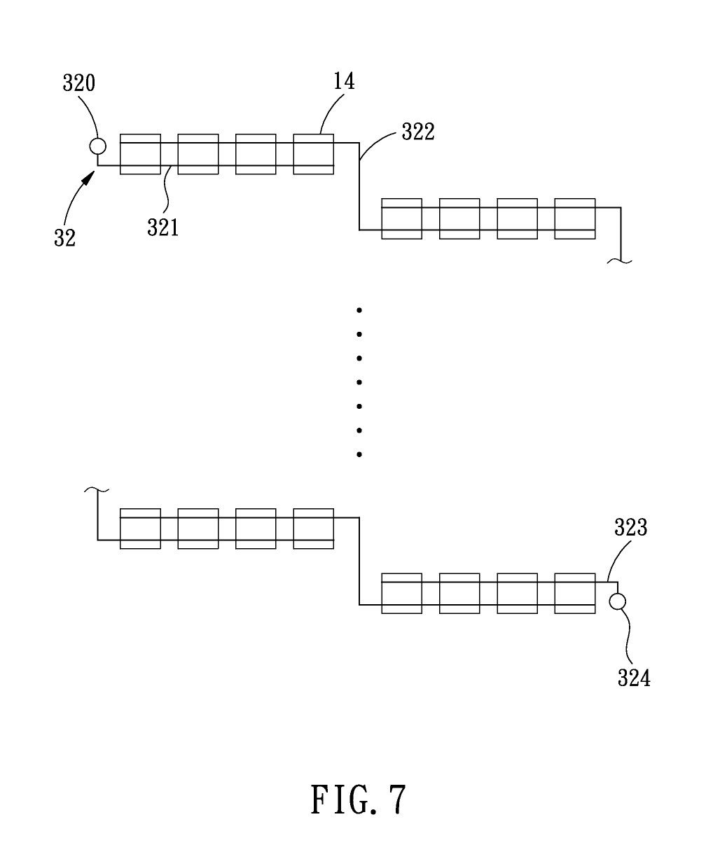

The conductive binders 32 on the cold end 301 of the ceramic heat conductive piece 30 are connected in series and in parallel manner, as shown in FIG. 7. One end of a first one of the conductive binders 32 connected to the electric wire 13 serves as a first connecting point 320, and a first connecting wire 321 extends from the first connecting point 320, and a second connecting wire 322 formed by the conductive binders 32 is located a distance away from and parallel to the first connecting wire 321. A plurality of LEDs 14 is disposed between and connected in parallel manner by the first and second connecting wires 321, 322. Between another end of the second connecting wire 322 and a next connecting wire formed by the conductive binders 32 is further arranged a plurality of parallel connected LEDs 14, and then the respective loops formed by the parallel connected LEDs 14 are connected in series. One end of a last connecting wire 323 (which is the Nth connecting wire) serves as a second connecting point 324 which is connected to the electric wire 13 to form a closed loop. Hence, the whole closed loop consists of a plurality of LEDs 14 which are parallel connected in groups, and then the groups of the parallel connected LEDs 14 are connected in series with one another.

While we have shown and described various embodiments in accordance with the present invention, it should be clear to those skilled in the art that further embodiments may be made without departing from the scope of the present invention.

What is claimed is:

1. A method for assembling LEDs to a ceramic heat conductive piece comprises the following steps:
step of forming the ceramic heat conductive piece: mixing different ceramic materials together and subjecting the mixed ceramic materials to hot pressing to form the ceramic heat conductive piece, the ceramic heat conductive piece having a cold end:
step of forming a silver layer: subjecting a surface of the cold end of the ceramic heat conductive piece to sliver printing, drying process and silver reduction process to form the silver layer;
step of wiring: choosing conductive binders, and applying the conductive binders to the silver layer by coating process;
step of attaching and welding: attaching the LEDs between paired conductive binders by welding, so that the LEDs and the conductive binders form an electric circuit loop;
step of getting a finished product: after the LEDs are welded, the ceramic heat conductive piece is connected to power wires and a ground wire, so that a final product of ceramic heat conductive piece is obtained.

2. The method for assembling LEDs to a ceramic heat conductive piece as claimed in claim 1, wherein the ceramic heat conductive piece is formed by mixture of magnesium oxide, aluminum oxide or aluminum nitride, silicon dioxide, zinc oxide, niobium oxide or bismuth oxide or zirconium oxide, these ceramic materials, and proportions are such that 10-15% Magnesium oxide, 65-70% aluminum oxide or aluminum nitride, 10-15% silicon dioxide, 5-10% zinc oxide, 5-10% niobium oxide or bismuth oxide or zirconium oxide.

3. The method for assembling LEDs to a ceramic heat conductive piece as claimed in claim 1, wherein the hot pressing is performed at a temperature of 350-1400° C. and pressure of 150-250 tons for 1-15 seconds.

4. The method for assembling LEDs to a ceramic heat conductive piece as claimed in claim 1, wherein the sliver printing is performed along a predetermined route on the surface of the cold end to form the silver layer with a thickness of 0.1-0.5 mm, or the silver layer is applied by manual coating, the sliver layer is composed of 40-60% sliver powder, and 40-60% silica binder.

5. The method 50 for assembling LEDs to a ceramic heat conductive piece as claimed in claim 1, wherein the drying process is performed at a temperature of 120-200° C. for 8-22 minutes.

6. The method 50 for assembling LEDs to a ceramic heat conductive piece as claimed in claim 1, wherein the silver reduction process is performed at a temperature of 700-800 ° C. for 1-3 hours.

7. The method for assembling LEDs to a ceramic heat conductive piece as claimed in claim 1, wherein the conductive binders is tin paste composed of 50-60% Tin and 40-50% additive.

8. The method for assembling LEDs to a ceramic heat conductive piece as claimed in claim 1, wherein the electric circuit loop has a voltage below volts and a current of 250 mA, one end of a first one of the conductive binders connected to the electric wire 13 serves as a first connecting point, and a first connecting wire extends from the first connecting point, and a second connecting wire formed by the conductive binders is located a distance away from and parallel to the first connecting wire, a plurality of LEDs is disposed between and connected in parallel manner by the first and second connecting wires, between another end of the second connecting wire and a next connecting wire formed by the conductive binders is further arranged a plurality of parallel connected LEDs, and then the respective loops formed by the parallel connected LEDs are connected in series, one end of a last connecting wire serves as a second connecting point which is connected to the electric wire to form a closed loop.

9. The structure produced by the method as claimed in claim 1, wherein the ceramic heat conductive piece is disposed in a LED lamp which comprises a lamp holder and a lamp shell mounted on the lamp holder, the lamp holder comprises a housing which has one end for mounting the lamp shell and has another end formed with an electric connecting portion for electrically connecting to power source, the electric connecting portion is electrically connected to the LEDs disposed inside the housing by electric wires, and another side of the ceramic heat conductive piece is connected to one end of a heat dissipation member, another end of the heat dissipation member is fixed to a bottom of the housing, the ceramic heat conductive piece has a cold end facing the LEDs and a heat end facing the heat dissipation member;
the heat dissipation member includes a heat conductive panel which is the same size as the ceramic heat conducive piece, the heat conductive panel has a side contacting the ceramic heat conducive piece, and another side of the heat conducive panel is provided at a center thereof with a central rod, and a fixing pin is inserted through a center of the central rod and into the bottom of the housing, a plurality of wings is arranged around the central rod in a radial manner and extends from the heat conductive panel;
at the bottom of the housing is further provided a plurality of holes.
